(19) United States
(12) Patent Application Publication
(10) Pub. No.: US 2010/0161258 A1
(43) Pub. Date: Jun. 24, 2010

(54) Measurement apparatus and system capable of displaying battery power

(75) Inventors: Sheng-Hung Lin, Hsinchu (TW); Che-Chang Chang, Hsinchu (TW)

Correspondence Address: Sheng-Hung Lin, P.O. Box 44-2049, Taipei, 10668, TW

(73) Assignee: Grenergy Opto, Inc.

(21) Appl. No.: 12/318,068

(22) Filed: Dec. 22, 2008

(51) Int. Cl. G01R 31/36

(52) U.S. Cl. 702/63

(57) ABSTRACT

A measurement apparatus capable of displaying battery power includes a battery cell, a measurement chip and an information display unit. The battery cell stores the battery power. The measurement chip further includes an acquiring unit, a converting unit, a processing unit and a display driving unit. The acquiring unit acquires the battery power from the battery cell to generate a first power signal. The converting unit converts the first power signal into a second power signal. The processing unit analyzes and computes the second power signal to provide battery power information. The display driving unit drives the information display unit. The battery power information can selectively represent the battery power corresponding to the battery cell to a user through the display driving unit.

### BACKGROUND OF THE INVENTION

(1) Field of the Invention

The invention relates to a measurement apparatus capable of displaying battery power, and more particularly to a measurement apparatus, in which a display driving unit is provided to drive an information display unit, and a measurement chip is provided to measure battery power so that the information display unit displays a residual capacity or a condition of used power of the battery power.

(2) Description of the Prior Art

In the conventional battery management technology, displaying the residual capacity of the battery (especially the precision of the residual capacity) is a very important issue. For example, it is assumed that the indication of the residual capacity of the mobile telephone only has three bars. When three bars are displayed, it represents that the battery has entered a fully charged state. When only two bars are displayed, it represents that some electric power has been consumed. When only one bar is displayed, it represents that the battery has entered a low-capacity state. When no bar is displayed, the mobile phone may be momentarily shut down. Alternatively, the three-bar capacity indication may be used in conjunction with a flicker function display.

However, when the three-bar capacity indication is used in conjunction with a flicker or flicker-free function display, its internal residual capacity detecting method is actually the roughest voltage detecting method. So, the residual capacity detecting method has the greater error in precision. With the change in the society, the users greatly need the mobile electronic applications, especially the mobile telephone or the notebook computer, and cannot accept the rough residual capacity display because the users may make mis-judgement according to the residual capacity indication with the too large deviation.

In addition to the unacceptable rough display method of the battery capacity, the battery residual capacity cannot be read until a display screen, such as a charger in the display screen of the mobile telephone or the notebook computer, is used. When a battery is obtained, the user cannot directly obtain the residual capacity of the battery body.

Furthermore, although an integrated circuit for measuring the battery power is available, it cannot be conveniently used. For example, the user cannot directly obtain the required battery power information through the battery. Although the battery power message can be obtained through an external device with a host, the capacity display is not precise.

In view of this, a measurement apparatus capable of displaying battery power is greatly needed to solve the conventional drawbacks.

### SUMMARY OF THE INVENTION

One aspect of the invention is to provide a measurement apparatus capable of displaying battery power, in which a display driving unit in a measurement chip is provided to drive an information display unit to display battery power information so that the information display unit displays a residual capacity or a condition of used power of the battery power.

Another aspect of the invention is to provide a measurement system capable of displaying battery power, wherein a display driving unit is provided to drive an information display unit, and a measurement chip is electrically connected to a display unit of a host through a control communication interface so that the battery power is analyzed and computed and a battery power signal is provided and represented to a user. Thus, the host can display the battery power signal, and the user may further be provided with a more precise battery power residual capacity or a condition of used power directly through the display driving unit of the measurement chip on the battery cell.

Still another aspect of the invention is to provide a battery device capable of displaying battery power, wherein a display driving unit of a measurement chip is provided to drive an information display unit to display battery power information so that the user can see the information on the information display unit.

In one embodiment, a measurement apparatus capable of displaying battery power is provided. The measurement apparatus includes a battery cell, a measurement chip and an information display unit. The battery cell stores the battery power. The measurement chip further includes an acquiring unit, a converting unit, a processing unit and a display driving unit. The acquiring unit acquires the battery power from the battery cell to generate a first power signal. The converting unit converts the first power signal into a second power signal. The processing unit analyzes and computes the second power signal to provide battery power information. The display driving unit drives the information display unit. The battery power information may selectively represent the battery power corresponding to the battery cell to a user through the display driving unit.

In another embodiment, a measurement system capable of displaying battery power is provided. The measurement system includes a host, a battery cell, a measurement chip and a control communication interface. The battery cell stores the battery power. The measurement chip further includes an acquiring unit, a converting unit, a processing unit and a display driving unit. The acquiring unit acquires the battery power from the battery cell to generate a first power signal. The converting unit converts the first power signal into a second power signal. The processing unit analyzes and computes the second power signal to provide battery power information. The display driving unit drives an information display unit. The control communication interface is electrically connected to the host, the battery cell and/or the measurement chip, and transfers the battery power information. The battery power information may selectively represent the battery power corresponding to the battery cell to a user through the display driving unit.

Further aspects, objects, and desirable features of the invention will be better understood from the detailed description and drawings that follow in which various embodiments of the disclosed invention are illustrated by way of examples.

### BRIEF DESCRIPTION OF THE DRAWINGS

FIG. 1 is a block diagram showing a measurement apparatus capable of displaying battery power according to a first embodiment of the invention.

FIG. 2 is block diagram showing a measurement apparatus capable of displaying battery power according to a second embodiment of the invention.

FIG. 3 is block diagram showing a measurement apparatus capable of displaying battery power according to a third embodiment of the invention.

### DETAILED DESCRIPTION OF THE PREFERRED EMBODIMENTS

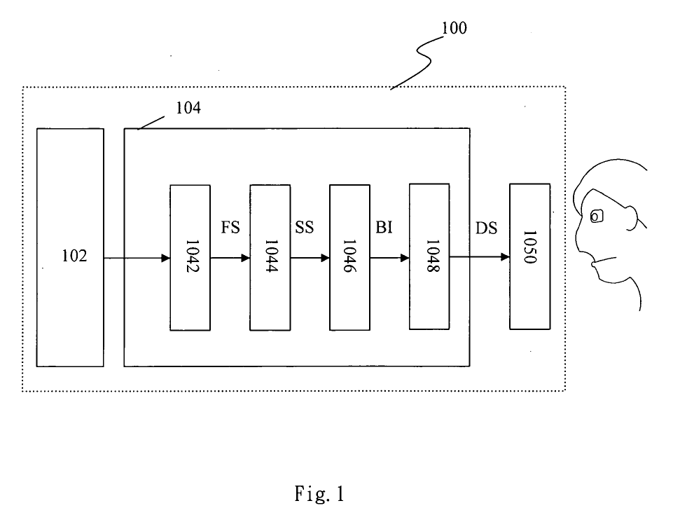

The invention discloses a measurement apparatus capable of displaying battery power, in which a display driving unit of a measurement chip is utilized to drive an information display unit, and the measured battery power is represented to the user. In order to make the description of the invention become more detailed and completed, illustrations will be made with reference to FIG. 1 to FIG. 3.

FIG. 1 is a block diagram showing a measurement apparatus capable of displaying battery power according to a first embodiment of the invention. Referring to FIG. 1, a battery power measurement apparatus 100 of this embodiment includes a battery cell 102 and a measurement chip 104. The battery cell 102, such as a primary battery or a secondary battery, stores the battery power. For example, the secondary battery is a lithium battery, a fuel battery or a nickel-metal-hydride battery. The measurement chip 104 further includes an acquiring unit 1042, a converting unit 1044, a processing unit 1046 and a display driving unit 1048. The acquiring unit 1042 acquires the battery power from the battery cell 102 to generate a first power signal FS. For example, the acquiring unit 1042 acquires the voltage, or current of the battery power etc. The converting unit 1044, such as a digital-to-analog converter (DAC) or an analog-to-digital converter (ADC), converts the first power signal FS into a second power signal SS. The processing unit 1046 analyzes and computes the second power signal SS to provide a battery power signal BI. For example, the processing unit 1046 analyzes and computes the residual capacity, the remaining operating time, the voltage, the temperature and the average current of the battery cell 102. The display driving unit 1048 receives the battery power signal BI and generates a driving signal DS to drive an information display unit 1050. The information display unit 1050 receives the driving signal DS so that the battery power corresponding to the battery cell 102 may be represented to the user. For example, the display unit 1050 is a light-emitting diode (LED), a liquid crystal display (LCD), a seven-segment display, a cold light display or a combination thereof.

The measurement apparatus 100 is implemented in a host-free electronic device having no host, such that the battery cell 102 can achieve the measurement apparatus capable of displaying the battery power signal BI through its own display driving unit 1048. For example, the battery power signal BI is the remaining operating time and the residual capacity. The user may drive the information display unit 1050 through the display driving unit 1048 so that the user can directly obtain the battery power signal BI of the battery cell 102. Preferably, it is unnecessary to connect the battery cell 102 to an external display mechanism apparatus in this embodiment, while the user can get the battery power signal BI of the battery cell 102.

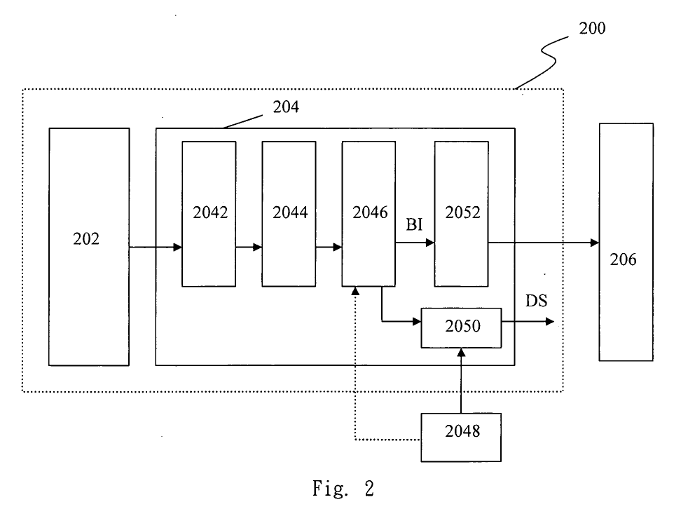

FIG. 2 is block diagram showing a measurement apparatus capable of displaying battery power according to a second embodiment of the invention. Referring to FIG. 2, the battery power measurement apparatus 200 includes a battery cell 202, a measurement chip 204, an acquiring unit 2042, a converting unit 2044, a processing unit 2046 and a display driving unit 2050, which are the same as the corresponding elements of the first embodiment, and further includes a button 2048, a control communication interface 2052 and a display unit 206. The button 2048 is connected to the display driving unit 2050 and/or the processing unit 2046 and selectively enables the function of displaying the battery power. The display driving unit 2050 provides a driving signal DS so that the user can obtain the precise battery power information BI through an information display unit (not shown). The control communication interface 2052 transfers the battery power information BI to the external display unit 206 (or an information display device with a host). The control communication interface 2052 may be a serial control communication interface or a parallel control communication interface. For example, the serial control communication interface may be I²C, SMbus or a combination thereof. In this embodiment, the display unit 206 is not an essential element and may be omitted.

In addition, when the battery cell 202 is charged through the mains or other methods, the processing unit 2046 of the measurement chip 204 may also directly make the analysis and provide the time, for which the battery cell 202 is fully charged, to the display unit for displaying the time. Furthermore, in order to achieve the power-saving function, the display driving unit 2050 does not provide the driving signal DS when it is ordinarily used. The user can press the button 2048 on the battery power measurement apparatus 200 when he or she needs to know the residual capacity of the battery so that the residual capacity can be selectively displayed.

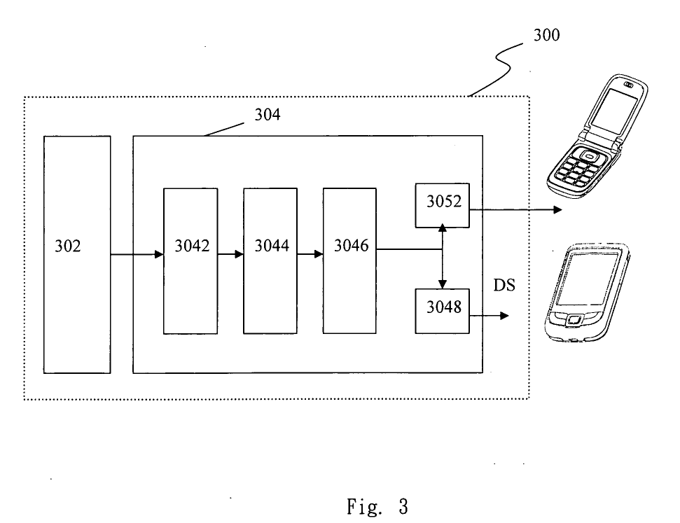

FIG. 3 is block diagram showing a measurement apparatus capable of displaying battery power according to a third embodiment of the invention. In this embodiment, a battery power measurement apparatus 300 is implemented on a host, such as a mobile phone or a personal mobile data assistant (PDA). A battery cell 302 stores the battery power. A measurement chip 304 includes an acquiring unit 3042, a converting unit 3044, a processing unit 3046, a display driving unit 3048 and a control communication interface 3052. The acquiring unit 3042 acquires the battery power from the battery cell 302 to generate a first power signal. The converting unit 3044 converts the first power signal into a second power signal. The processing unit 3046 analyzes and computes the second power signal to provide a battery power signal, which is represented to the user through the battery cell 302. The display driving unit 3048 receives the battery power signal and generates the driving signal DS. The control communication interface 3052 is electrically connected to the host, the battery cell 302 and/or the measurement chip 304, and transfers the battery power signal. In addition, the battery power measurement apparatus 300 may also be integrated in the host, and the battery power information may be transferred to the host through the control communication interface 3052. More particularly, the user can obtain a rough remaining capacity of the battery through the remaining capacity display on the host, and may also obtain a driving signal DS directly from the display driving unit 3048 of the measurement chip 304 on the battery cell, and drive the information display unit (not shown) so that the more precise battery power information than that of the host may be represented to the user.

In addition, the measurement chip 304 may further include a digital-to-analog converter (DAC) or an analog-to-digital converter (ADC) (not shown) for converting the battery power signal into an analog (or a digital) power signal. Thus, the analog (or digital) power signal may be directly provided to an analog (or a digital) display unit, which may represent the signal to the user. For example, a pointer type device for displaying the analog remaining capacity of the battery cell may be used to display the analog power signal.

New characteristics and advantages of the invention covered by this document have been set forth in the foregoing description. It is to be expressly understood, however, that the drawings are for the purpose of illustration only and are not intended as a definition of the limits of the invention. Changes in methods, shapes, structures or devices may be made in details without exceeding the scope of the invention by those who are skilled in the art. The scope of the invention is, of course, defined in the language in which the appended claims are expressed.

What is claimed is:

1. A measurement apparatus capable of displaying battery power, the measurement apparatus being applied to a host-free electronic device, the measurement apparatus comprising:
a battery cell for storing the battery power;
a measurement chip, comprising:
an acquiring unit for acquiring the battery power from the battery cell to generate a first power signal;
a converting unit for converting the first power signal into a second power signal;
a processing unit for analyzing and computing the second power signal to provide battery power information; and
a display driving unit for driving an information display unit,
wherein the battery power information may selectively represent the battery power corresponding to the battery cell to a user through the display driving unit.

2. The apparatus according to claim 1, wherein the measurement chip further comprises a button, connected to the information display unit or the display driving unit, for selectively controlling the battery power information to be displayed.

3. The apparatus according to claim 1, wherein the battery cell is a primary battery or a secondary battery.

4. The apparatus according to claim 1, wherein the acquiring unit acquires a voltage, or a current of the battery power.

5. The apparatus according to claim 1, wherein the converting unit is an analog-to-digital converter (ADC) or a digital-to-analog converter (DAC).

6. The apparatus according to claim 1, wherein the processing unit analyzes and computes a residual capacity, a remaining operating time, a voltage, a temperature and an average current of the battery cell.

7. The apparatus according to claim 1, wherein the information display unit is a light-emitting diode (LED), a liquid crystal display (LCD), a seven-segment display, a cold light display or a combination thereof.

8. The apparatus according to claim 1, wherein the measurement chip further comprises a control communication interface for transferring the second power signal.

9. The apparatus according to claim 8, wherein the control communication interface is a serial control communication interface or a parallel control communication interface.

10. The apparatus according to claim 9, wherein the serial control communication interface is I²C, SMbus or a combination thereof.

11. A measurement system capable of displaying battery power, the system comprising:
a host;
a battery cell for storing the battery power;
a measurement chip, which comprises:
an acquiring unit for acquiring the battery power from the battery cell to generate a first power signal;
a converting unit for converting the first power signal into a second power signal;
a processing unit for analyzing and computing the second power signal to provide battery power information;
a display driving unit for driving an information display unit; and
a control communication interface, electrically connected to the host, the battery cell and/or the measurement chip, for transferring the battery power information;
wherein the battery power information may selectively represent the battery power corresponding to the battery cell to a user through the display driving unit.

12. The system according to claim 11, wherein the battery cell is a primary battery or a secondary battery.

13. The system according to claim 11, wherein the acquiring unit acquires a voltage, or a current of the battery power.

14. The system according to claim 11, wherein the converting unit is an analog-to-digital converter (ADC) or a digital-to-analog converter (DAC).

15. The system according to claim 11, wherein the processing unit analyzes and computes a residual capacity, a remaining operating time, a voltage, a temperature and an average current of the battery cell.

16. The system according to claim 11, wherein the information display unit is a light-emitting diode (LED), a liquid crystal display (LCD), a seven-segment display, a cold light display or a combination thereof.
